(19) United States
(12) Patent Application Publication
(10) Pub. No.: US 2012/0132464 A1
(43) Pub. Date: May 31, 2012

(54) METHOD FOR MANUFACTURING PRINTED WIRING BOARD, PRINTED WIRING BOARD, AND ELECTRONIC DEVICE

(75) Inventors: Hideaki YOSHIMURA, Kawasaki (JP); Naohito MOTOOKA, Kawasaki (JP); Yasuhiro KARAHASHI, Kawasaki (JP); Asami HONDO, Kawasaki (JP); Satoshi YAMAGISHI, Kawasaki (JP); Hiromitsu KOBAYASHI, Kawasaki (JP)

(73) Assignee: FUJITSU LIMITED, Kawasaki-shi (JP)

(21) Appl. No.: 13/297,819

(22) Filed: Nov. 16, 2011

(30) Foreign Application Priority Data
Nov. 25, 2010 (JP) 2010-262890

(51) Int. Cl. H05K 1/11; H05K 3/40

(52) U.S. Cl. 174/266; 29/850

(57) ABSTRACT

A method for manufacturing a printed wiring board includes filling material in through holes formed in first lands on a first substrate, forming projection portions projecting from the first lands on the surface of the material of the through holes, placing a conductive material on the first lands, and electrically connecting the first lands of the first substrate and second lands of second substrate by pressing the conductive material under melting filled between the first and second lands in the lamination direction of the substrates by the projection portions when laminating the substrates in such a manner that the lands of the other substrate face the lands of the substrate for aggregation of the conductive material.

### CROSS-REFERENCE TO RELATED APPLICATION

This application is based upon and claims the benefit of priority from the prior Japanese Patent Application No. 2010-262890 filed on Nov. 25, 2010, the entire contents of which are incorporated herein by reference.

### FIELD

The embodiment discussed herein is related to a method for manufacturing a printed wiring board, a printed wiring board, and an electronic device.

### BACKGROUND

In recent years, printed wiring boards for semiconductor testers have been demanded for sharply increasing the number of wiring layers, which form the printed wiring boards, with an increase in the number of integrated memories, for example. Therefore, printed wiring boards having 60 or more wiring layers are not uncommon. Moreover, also in packaging printed wiring boards manufactured by a build-up method, when the line width of wires is reduced with a demand for an increase in density, the conductor resistance significantly increases to deteriorate the frequency characteristics in some cases. Then, an increase in the number of wires due to an increase in the number of terminals of semiconductor elements is addressed by an increase in the number of wiring layers in such a situation.

Therefore, with an increase in the number of wiring layers, a method is known which includes laminating two or more substrates in the thickness direction, and electrically bonding lands of one substrate and lands of the other opposite substrate with a conductive material. As a conductive material serving in a via for bonding the lands, a conductive paste of non-molten metal, such as silver or copper, is used. In this case, multilayer printed wiring boards are known in which a conductive paste is pressure-welded between the lands, and the lands are bonded with the pressure-welded conductive paste.

However, the reliability of the bonding between the lands achieved by pressure welding using non-molten metal is low to stress generated due to heat distortion or the like in the case of, for example, high multilayer large-sized printed wiring boards. Thus, a method for bonding the lands with low melting point metals of metallic compounds, such as soldering, is preferable, for example. In addition, in the case where the low melting point metals completely melt, and then the molten metals aggregate to thereby form a lump of via, the resistance to electro migration also increases, so that a current that may be sent to the via also becomes high. Therefore, with an increase in the number of wiring layers, a demand for a method for the bonding lands using low melting point metals has increased.

Thus, in bonding the lands using low melting point metals, a printing method is used for filling the low melting point metals in many cases. In the printing method, a conductive material is used in which powder of low melting point metals is pasted. For the conductive material of low melting point metal paste, organic acid that activates adhesives and metallic powder is used in order to prevent remaining of uncured products.

However, the conductive material of low melting point metal paste contains an adhesive ingredient or the like containing a resin ingredient of at least about half of the entire volume because the conductive material is required to secure printing properties and viscosity considering filling properties, e.g., 100 to 350 Pa·S, (Pascal second). As a result, when the method for bonding the lands with the conductive material of low melting point metal paste is adopted, the electrical resistance between the lands is stable and the reliability of the bonding between the lands becomes high.

Known as the multilayer printed wiring board is a printed wiring board in which a via portion of a first substrate and a via portion of a second substrate are bonded with a bonding material. On the surface of the first substrate, a projection portion to be connected to the via portion at the first substrate side is formed. A pressure is applied in the direction in which the first substrate and the second substrate face each other with an adhesion layer interposed between the first substrate and second substrate to thereby laminate the substrates. As a result, the projection portion at the first substrate side may be electrically connected to the via portion at the second substrate side.

FIGS. 12 and 13 illustrate views for describing the state of a bonded portion between the lands with a conductive material. In FIG. 12, when laminating substrates 100A and 100B with an adhesion layer of a prepreg 101 interposed there between, a conductive material of low melting point metal paste 103 is placed between a land 102 at the side of one substrate 100A and a land 102 at the side of the other substrate 100B. Then, due to aggregation of the conductive material under melting between the lands 102, the lands 102 are bonded due to the aggregation of the conductive material 103. However, in the conductive material 103, a resin ingredient occupies about half of the entire volume thereof. As a result, when metal particles of metallic powder contacting in the conductive material 103 melt, and then start to aggregate, the distance between the metal lumps aggregated in the aggregation process becomes greater as illustrated in FIG. 12, so that poor electrical connection occurs in the bonded portion between the lands 102. Moreover, as illustrated in FIG. 13, when the aggregation of the metal particles under melting becomes insufficient, the metal particles do not contact each other and remain in the state of particles without aggregation in a cured product, so that poor electrical connection occurs in the bonded portion between the lands 102.

Thus, it is supposed that the substrates are pressed in such a manner that the thickness of the bonded portion between the lands is reduced to reach about half of the entire volume of the low melting point metal paste used as the conductive material, i.e., the volume fraction of the resin ingredient. In this case, the metal particles in the low melting point metal paste are brought into surface-to-surface contact with each other, so that the bonded portion between the lands may be electrically connected. However, when laminating the substrates, the melt viscosity of the prepreg of an adhesive ingredient for pasting the substrates needs to be highly set to some extent in order to prevent the metallic powder in the low melting point metal paste from flowing and scattering. Therefore, with the pressure for laminating the substrates, the thickness of the adhesion layer may not be made small even when the adhesion layer of the prepreg is excessively pressed.

FIG. 14 illustrates a view for experimentally describing the remaining copper ratio of the substrates when laminating the substrates using a 70 μm thick prepreg and the distance between the lands after laminating the substrates, i.e., the thickness of the bonded portion. The distance between the lands, i.e. the thickness of the bonded portion, is defined as H and the remaining copper ratio indicating the surface area ratio of a copper portion of a wiring pattern, such as the land on the substrate surface, to the surface area of the substrate surface is defined as R. Furthermore, the thickness of the prepreg is defined as t1 and the thickness of the wiring pattern is defined as t2. The remaining copper ratio R of each substrate to be laminated is the same value. The distance between the lands, i.e., the thickness H of the bonded portion, may be calculated based on H=t1−2·(1−R)×t2. As a result, the thickness H of the bonded portion does not depend on the pressure in the lamination direction and the thickness is fixed at about 40 μm when the remaining copper ratio R reaches 60% or lower. More specifically, the fact that the thickness H of the bonded portion is fixed refers to the fact that the thickness of woven fabric of glass fiber for use in the prepreg of the adhesion layer is about 40 μm, and even when the glass fiber is excessively pressed, the thickness does not become small. Therefore, it is found that even when the pressure for laminating the substrates is excessively high, the remaining copper ratio R decreases and the thickness of the bonded portion between the lands may not be made small.

When summarizing the description above, in the conductive material of low melting point metal paste, resin ingredients occupy about half of the entire volume of the conductive material in order to secure printing properties and viscosity. As a result, in the bonded portion where the lands are bonded with the conductive material of low melting point metal paste, the conductive material melts and separates in an aggregation process after melting or the conductive material remains in the state of metal particles without contacting each other and without aggregation in a cured product, so that poor electrical connection occurs in the bonded portion between the lands.

When materials having the same particle size are used as a material that does not completely melt in the low melting point metal paste (metal material whose surface is solder plated, for example), a space that absorbs 0.9 fold resin, as indicated by (2r)3:4·π·r3/3≈1.9:1, is formed between the space of the particles. Therefore, the resin volume may be absorbed in the gap between the particles bit the metal particles are brought in to point-to-point contact with each other, so that the allowable current quantity that may be passed to the bonded portion bonded with the conductive material decreases. Furthermore, according to a pressure welding method using non-molten metals, such as silver or copper, the metal particles are brought into point-to-point contact with each other, and thus the distortion resistance is low and the reliability is low.

The followings are reference documents.

[Document 1] Japanese Laid-open Patent Publication No. 7-176846.

[Document 2] Japanese Laid-open Patent Publication No. 2003-142827.

[Document 3] Japanese Laid-open Patent Publication No.2000-269647.

[Document 4] Japanese Laid-open Patent Publication No.6-268376.

[Document 5] Japanese Laid-open Patent Publication No.2000-294931.

### SUMMARY

According to an aspect of the embodiment, a method for manufacturing a printed wiring board includes filling material in through holes formed in first lands on a first substrate, forming projection portions projecting from the first lands on the surface of the material of the through holes, placing a conductive material on the first lands and electrically connecting the first lands of the first substrate and second lands of second substrate by pressing the conductive material under melting filled between the first and second lands in the lamination direction of the substrates by the projection portions when laminating the substrates in such a manner that the lands of the other substrate face the lands of the substrate for aggregation of the conductive material.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates a cross sectional view in which a portion of a printed wiring board of this Example is omitted;

FIG. 2 illustrates views for describing manufacturing processes of a substrate;

FIG. 3 illustrates views for describing manufacturing processes of the substrate;

FIG. 4 illustrates views for describing manufacturing processes of the substrate focusing on manufacturing of a projection portion among the manufacturing processes;

FIG. 5 illustrates views for describing manufacturing processes of the substrate focusing on manufacturing of a projection portion among the manufacturing processes;

FIG. 6 illustrates views for describing manufacturing processes of a projection portion of a Comparative Example;

FIG. 7 illustrates views for describing manufacturing processes of the projection portion of the Comparative Example;

FIG. 8 illustrates views for describing manufacturing processes of a printed wiring board;

FIG. 9 illustrates views for describing the state of a conductive material between lands among the manufacturing processes of the printed wiring board;

FIG. 10 illustrates views for describing the state of a conductive material between lands among manufacturing processes of a printed wiring board of another example;

FIG. 11 illustrates a cross sectional view in which a portion of a printed wiring board of another example is omitted;

FIG. 12 illustrates a view for describing the state of a bonded portion between lands with a conductive material;

FIG. 13 illustrates a view for describing the state of a bonded portion between lands with a conductive material; and

FIG. 14 illustrates a view experimentally describing the remaining copper ratio of substrates when laminating the substrates using a 70 μm thick prepreg and the distance between the lands after laminating the substrates, i.e., the thickness of the bonded portion.

### DESCRIPTION OF EMBODIMENTS

Hereinafter, Examples of a method for manufacturing a printed wiring board, a printed wiring board, and an electronic device disclosed in this application will be described in detail with reference to the drawings. The disclosed techniques are not limited to the Examples.

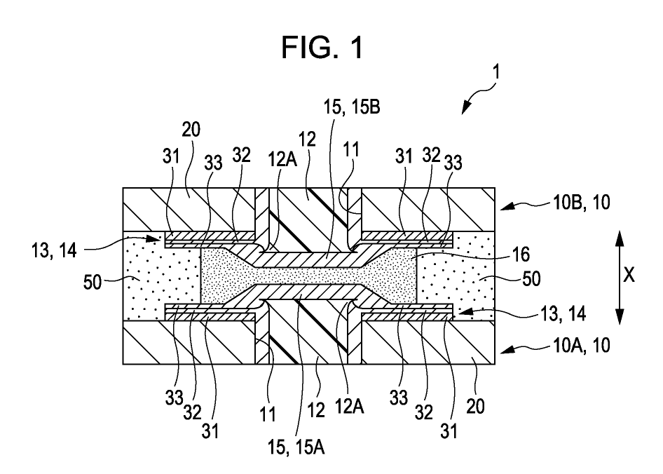

FIG. 1 is a cross sectional view in which a portion of a printed wiring board of this Example is omitted. In a printed wiring board 1 illustrated in FIG. 1, a first substrate 10A and a second substrate 10B are laminated with an adhesion layer 50 interposed there between, and the first substrate 10A and the second substrate 10B are electrically connected by a conductive material 16. The first substrate 10A has a base material 20, a through hole 11 penetrating in the thickness direction of the base material 20, a hole filling material 12 that is filled in the through hole 11, and a wiring pattern 13 formed on the base material surface. The wiring pattern 13 includes a conductor circuit, a land 14, or the like. The land 14 is disposed concentrically with the through holes 11 and is electrically connected to the through hole 11. On the land 14, a projection portion 15 (15A) is further formed using an end portion 12A of the hole filling material 12 projecting on the surface of the base material 20 described later.

The projection portion 15 has a three layer structure of a copper foil layer 31 on the surface of the base material 20, a copper plating layer 32 formed on the copper foil layer 31 for copper plating the inner wall surface of the through hole 11, and a cap plating layer 33 formed when cap plating the end portion 12A of the hole filling material 12.

The second substrate 10B also similarly has the through hole 11, the hole filling material 12, and the wiring pattern 13. On the land 14 of the wiring pattern 13, a projection portion 15 (15B) is formed.

In the printed wiring board 1, the first substrate 10A and the second substrate 10B are laminated with the adhesion layer 50 interposed there between. When laminating the first substrate 10A and the second substrate 10B, the conductive material 16 under melting placed between the lands 14 is pressed in the lamination direction X by a projection portion 15A of the first substrate 10A and a projection portion 15B of the second substrate 10B. Then, by pressing the conductive material 16 in the lamination direction X by each of the projection portions 15 (15A, 15B), the metal particles in the conductive material 16 are brought into surface-to-surface contact with each other and aggregated. As a result, a cured product of the aggregated conductive material 16 achieves electrically connection between the lands 14.

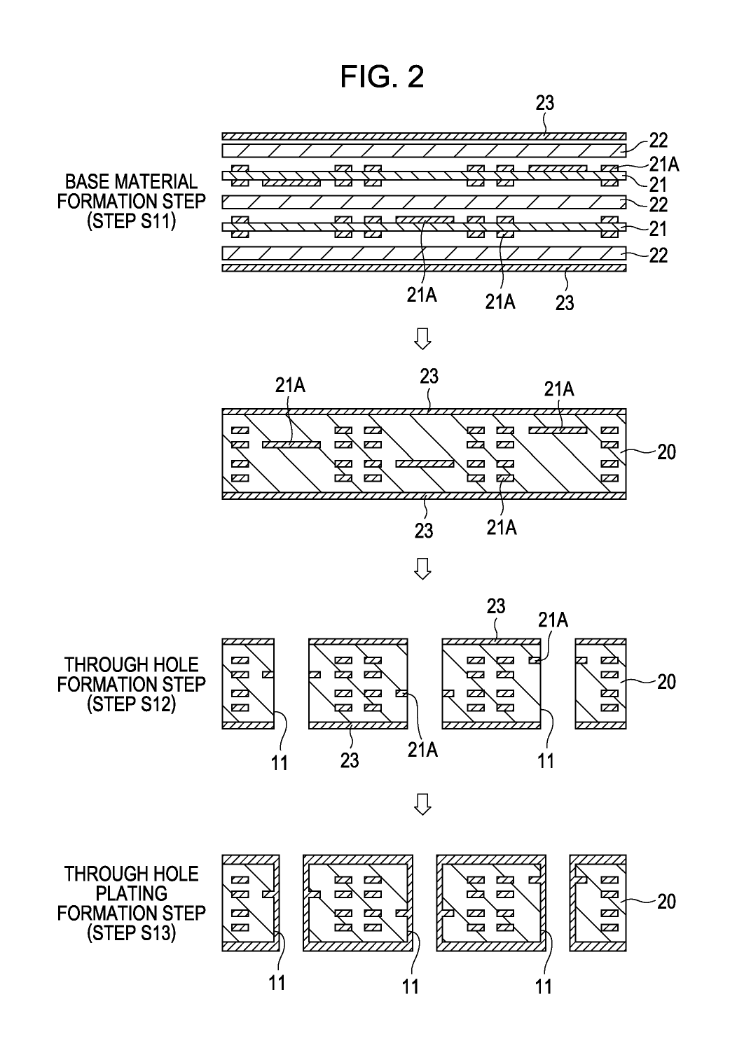

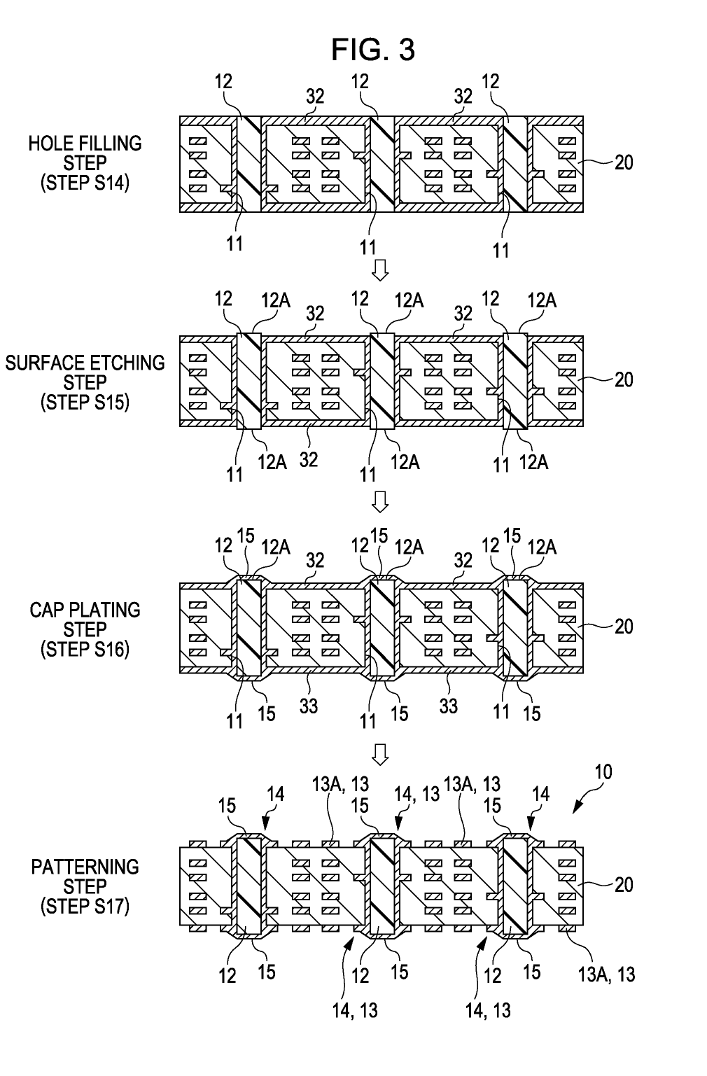

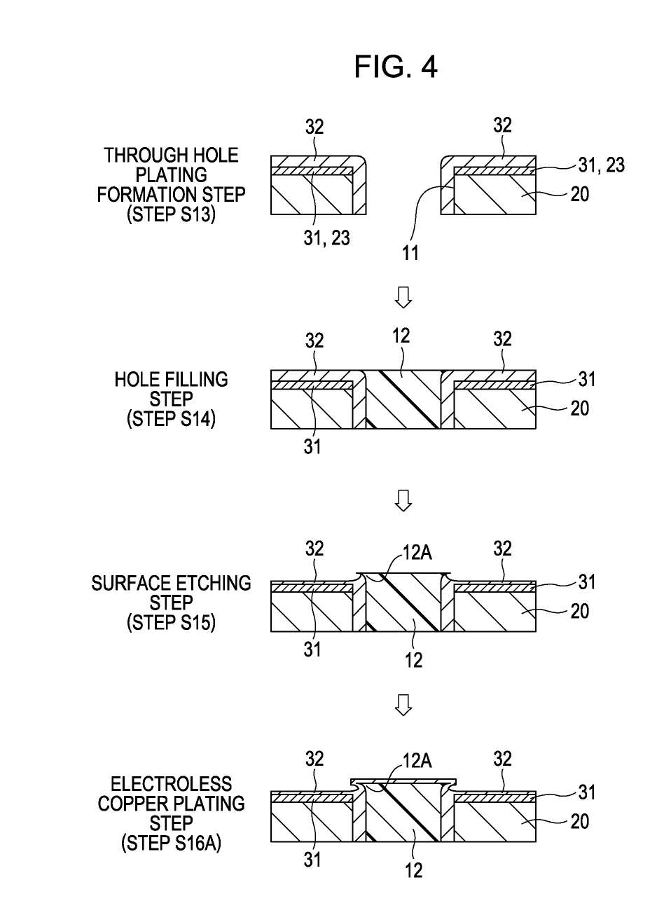

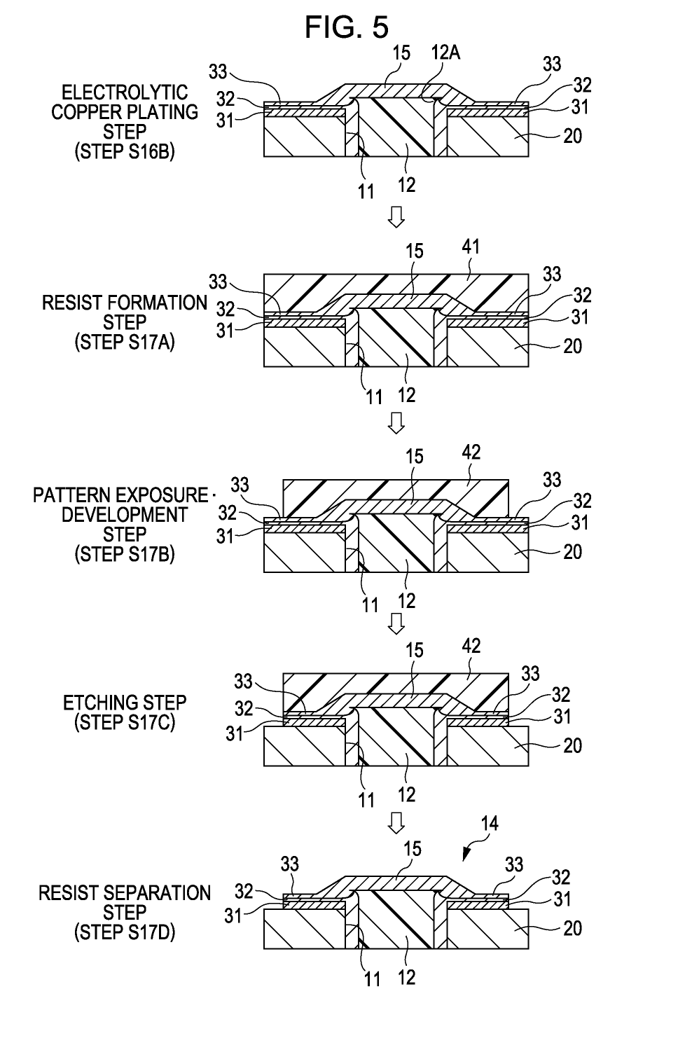

Next, a manufacturing process of the printed wiring board 1 of this Example will be described. FIGS. 2 and 3 illustrate views for describing manufacturing processes of the substrate 10. FIGS. 4 and 5 illustrate views for describing manufacturing processes of the substrate 10 focusing on the manufacturing of the projection portion 15 among the manufacturing processes. The substrate 10 is equivalent to the first substrate 10A, the second substrate 10B, or the like described above, for example. In a base material formation process (Step S11) illustrated in FIG. 2, a resist for forming a circuit is applied onto a copper foil of a CCL (Copper Clad Laminate), a wiring pattern is exposed and developed, and thereafter the copper foil is etched to thereby form intermediate layers 21 having wiring patterns 21A formed on both surfaces. The CCL is obtained by laminating a prepreg, such as woven fabric of glass fibers which are impregnated with insulating resin, and a copper foil by heating press.

In the base material formation process, a given number of the intermediate layers 21 are disposed in a lamination manner, the prepregs 22 are disposed in such a manner as to sandwich these intermediate layers 21, and copper foils 23 are disposed on the back and front. For the copper foils 23, a 18 μm foil or a 35 μm foil is used. Then, in the base material formation process, the base material 20 is formed by laminating these intermediate layers 21, the prepregs 22, and the copper foils 23 while heating and pressurizing them by vacuum press. In the base material 20, a touring hole for lamination, which is not illustrated, is formed by drill processing.

In a through hole formation process (Step S12), the through holes 11 connecting the wiring patterns 21A of the intermediate layers 21 and the copper foils 23 on the back and front were formed in the base material 20. The inner diameter of the through holes 11 was set to φ0.2 mm, for example. In a through hole plating formation process (Step S13), the inner wall surface of the through holes 11 was copper plated. The thickness of the copper plating layer 32 of the inner wall surface of the through hole 11 was set to 25 μm, for example. In this case, in the portions of the through holes 11 of the base material 20, the copper plating layers 32 was formed on the copper foil layers 31 of the copper foils 23 as illustrated in a through hole plating process of FIG. 4.

Next, in a hole filling process (Step S14) illustrated in FIG. 3, the hole filling material 12 is filled in the through holes 11 of the base material 20. For the hole filling material 12, epoxy resin, to which a silica filler is added, e.g., resin having a coefficient of thermal expansion of about 30 ppm/° C., is used in order to adjust the coefficient of thermal expansion in the thickness direction of the base material 20 to about 33 ppm/° C., for example. When the coefficient of thermal expansion of the base material 20 and the coefficient of thermal expansion of the hole filling material 12 are made closer, the stress to be applied to the bonded portion of the base material 20 and the hole filling material 12 may be made small.

In the hole filling process, before filling the hole filling material 12 in the through holes 11, the inner wall surface of the through holes 11 and the surface of the base material 20 are subjected to roughening treatment. The roughening treatment is treatment including immersing the copper plating layers 32 of the inner wall surface of the through holes 11 and the copper foil layers 31 and the copper plating layers 32 on the surface of the base material 20 in a mixed liquid of formic acid and hydrochloric acid, washing away the mixed liquid by washing with water, and then subjecting the surface to roughening treatment. As a result, when the inner wall surface of the through holes 11 and the surface of the base material 20 are roughened, the interface of the outer peripheral surface of the hole filling materials 12 may be deeply etched in the following surface etching process. The situation where a plating liquid that permeates into the inner wall surface of the through holes 11 and the surface of the base material 20 and remains therein evaporates after laminating to form a void may be prevented before the situation occurs. More specifically, in the hole filling process, after the inner wall surface of the through holes 11 and the surface of the base material 20 are subjected to the roughening treatment and after the surface subjected to the roughening treatment is ground away by grinding the surface, the hole filling material 12 is filled in the through holes 11.

In a surface etching process (Step S15), after filling the hole filling materials 12 in the hole filling process, the irregularities on the surface of the copper plating layers 32 on the base material 20 are reduced, and then the surface of the copper plating layers 32 is ground by a ceramic roll in order to reduce the height variation thereof to about several micrometers. In the surface etching process, after grinding the surface, a given amount of the copper plating layers 32 is etched in order to leave about 15 to 20 μm of the copper plating layers 32 formed in the through hole plating formation process. As a result, as illustrated in the surface etching process of FIG. 4, the end portion 12A of the hole filling material 12 remains on the surface of the base material 20 in such a manner as to project by etching a given amount of the copper plating layer 32. For an etching solution, a hydrogen peroxide/sulfuric acid etching solution was used. For example, chemicals capable of melting copper, such as a cupric chloride solution, a ferric chloride solution, an alkali etching solution, or a persulfate solution, may be used.

In an nonelectrolytic copper plating process (Step S16A) illustrated in FIG. 4 illustrating a cap plating process (Step S16), after making the end portion 12A of the hole filling material 12 project to the surface of the base material 20 by the surface etching process, the surface is subjected to nonelectrolytic copper plating treatment. As a result, seed plating is given to the exposed surface of the hole filling material 12. As a result, seed plating is given to the exposed surface of the hole filling material 12. In an electrolytic copper plating process (Step S16B) illustrated in FIG. 5 illustrating the cap plating process, after giving the seed plating to the exposed surface of the hole filling material 12, electrolytic copper plating treatment is given to the surface of the base material 20. Then, the end portion 12A of the hole filling material 12 is subjected to cap plating to thereby form the projection portion 15 on the surface of the base material 20.

In the projection portion 15, the cross sectional shape was formed into an approximately trapezoidal shape in which the surface side of the base material 20 serves as the lower bottom. The outer peripheral edge portions of the projection portion 15 have a three layer structure of the copper foil layer 31 of the base material 20 formed in the base material formation process, the copper plating layer 32 formed in the through hole plating formation process and the surface etching process, and the cap plating layer 33 formed in the nonelectrolytic copper plating process and the electrolytic copper plating process.

In a resist formation process (Step S17A) illustrated in FIG. 5 illustrating a patterning process (Step S17), a resist 41 for circuit formation is applied onto the surface of the base material 20. In a pattern exposure and development process (Step S17B) illustrated in FIG. 5 illustrating the patterning process, after applying the resist 41 onto the surface, a given circuit pattern is exposed and developed to thereby form an etching resist 42 on the surface. In an etching process (Step S17C) illustrated in FIG. 5 illustrating the patterning process, the copper foil layer 31 and the copper plating layer 32 at a portion where the etching resist 42 is not formed are etched to thereby form a circuit pattern 13, such as the land 14 or a conductor circuit 13A, on the surface.

In a resist separation process (Step S17D) illustrated in FIG. 5 illustrating the patterning process, the wiring pattern 13, e.g., the land 14 having the projection portion 15, is formed on the surface of the base material 20 by separating the etching resist 42 on the surface. As a result, the substrate 10 was completed. On the land 14, the projection portion 15 having a diameter of φ0.25 mm and a height of about 15 μm, for example, was formed. Furthermore, the land 14 may be subjected to precious metal plating, such as gold plating, nickel plating effective as barrier metal, composite plating in which precious metal plating or nickel plating is combined, or the like.

Therefore, the projection portion 15 may be formed on the land 14 of the substrate 10 through easy processes to which the surface etching process illustrated in FIG. 4 is added.

The height of the projection portion 15 is adjusted by the thickness of the copper foil 23 (copper foil layer 31) laminated on the back and front of the base material 20 in the base material formation process but may be adjusted by the thickness of the copper plating layer 32 formed on the inner wall surface of the through hole 11 in the through hole plating formation process. Or, the height of the projection portion 15 may be adjusted by the etching amount in the surface etching process.

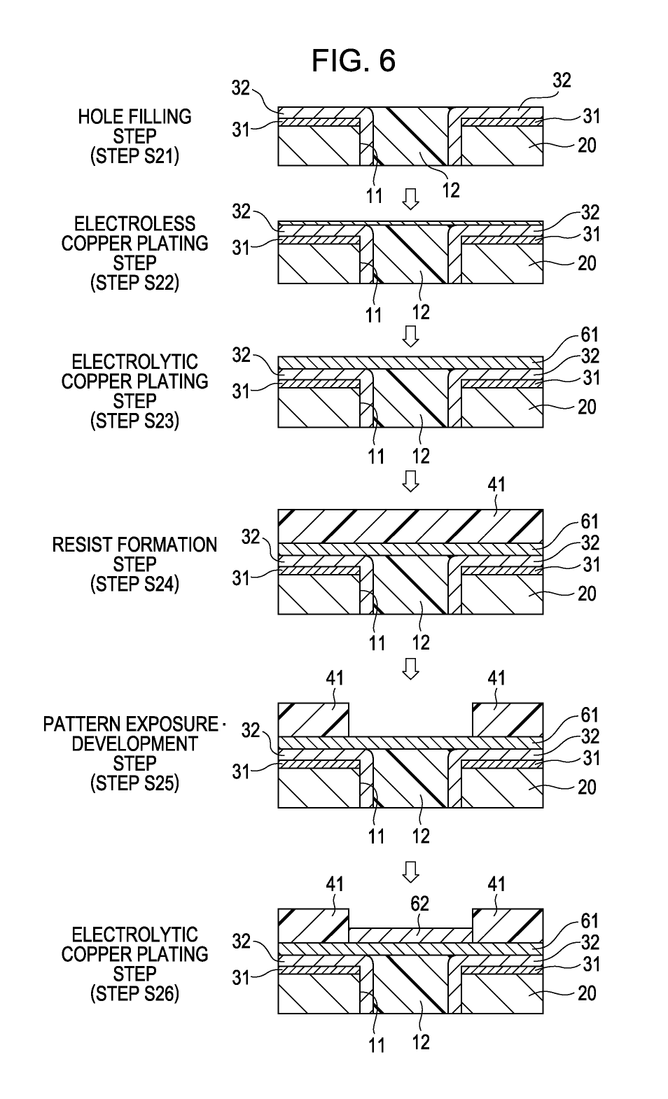

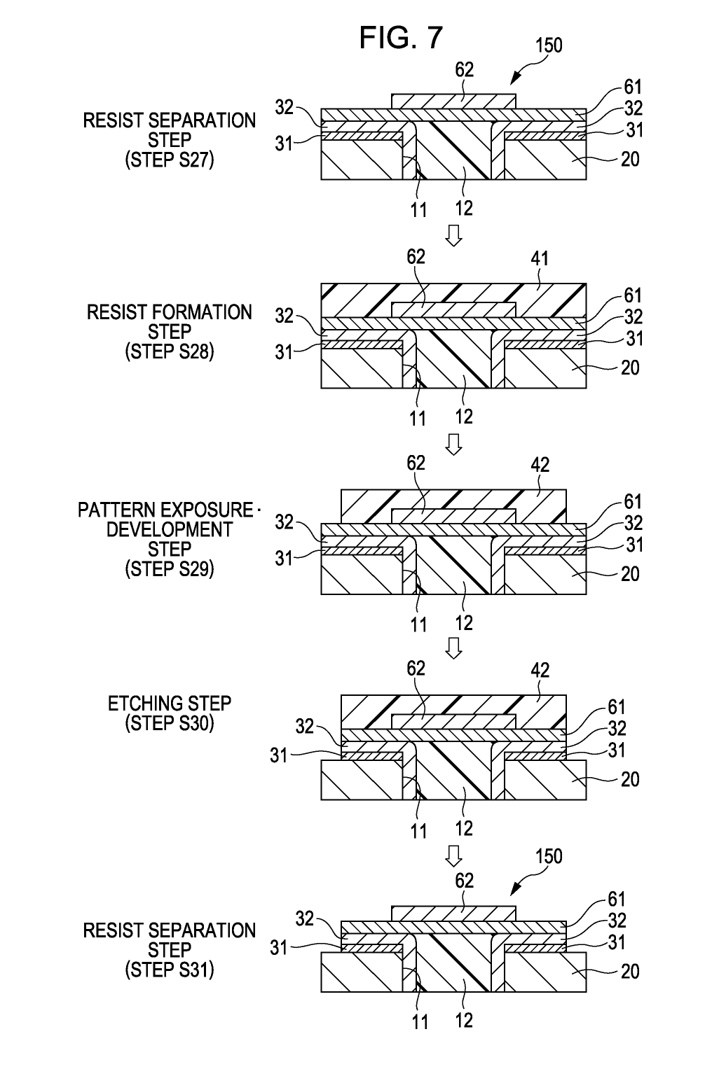

Next, manufacturing processes for forming the projection portion by processes different from the manufacturing processes illustrated in FIGS. 4 and 5 will be described as a Comparative Example. FIGS. 6 and 7 illustrate views for describing manufacturing processes of a projection portion of a Comparative Example. In the Comparative Example, a projection portion 150 is formed on the land 14 in a photolithography process. In the manufacturing processes illustrated in FIG. 6, processes to the hole filling process (Step S21) including filling the hole filling material 12 in the through hole 11 of the base material 20, and then grinding the surface are the same as the manufacturing processes illustrated in FIG. 4. In this case, at the through hole portion 11 of the base material 20, the copper plating layer 32 is formed on the copper foil layer 31 of the copper foil 23.

In an nonelectrolytic copper plating process (Step S22), after grinding the surface of the base material 20 in the hole filling process, nonelectrolytic copper plating treatment is given to the surface. As a result, seed plating is given to the exposed surface of the hole filling material 12. In an electrolytic copper plating process (Step S23), after the seed plating is given to the surface of the base material 20, electrolytic copper plating treatment is given to the surface of the base material 20 to thereby give cap plating to the exposed surface of the hole filling component 12. In this case, the through hole portion 11 of the base material 20 has a three layer structure of the copper foil layer 31, the copper plating layer 32, and a cap plating layer 61 formed by the nonelectrolytic copper plating treatment and the electrolytic copper plating treatment.

In a resist formation process (Step S24), after performing the electrolytic copper plating treatment, the resist 41 is applied onto the surface (cap plating layer 61) of the base material 20. In a pattern exposure and development process (Step S25), after applying the resist 41 onto the surface, a wiring pattern for forming the projection portion 150 is exposed and developed. Then, in the pattern exposure and development process, the resist 41 at the position where the projection portion 150 is to be formed is separated. In this case, in the pattern exposure and development process, the position where the projection portion 150, which is to be disposed concentrically with the through hole 11, is formed is recognized based on a touring hole formed in the base material 20.

In an electrolytic copper plating process (Step S26), by performing electrolytic copper plating treatment based on a circuit pattern for forming the projection portion 150, copper plating is given to the position where the projection portion 150 is to be formed. As a result, the projection plating layer 62 is formed on the cap plating layer 61 at the position where the projection portion 150 is to be formed. In a resist separation process (Step S27) illustrated in FIG. 7, by separating the resist 41 on the surface of the base material 20 after forming the projection plating layer 62 on the cap plating layer 61, the projection portion 150 projecting on the through hole 11 is formed. In this case, the projection portion 150 has a four layer structure of the copper foil layer 31, the copper plating layer 32, the cap plating layer 61, and the projection plating layer 62.

In a resist formation process (Step S28), after forming the projection portion 150 on the surface of the base material 20, the resist 41 for circuit formation is applied onto the surface of the base material 20. In a pattern exposure and development process (Step S29), after applying the resist 41 onto the surface of the base material 20, a circuit pattern for forming a circuit other than the projection portion 150, e.g., the land 14, is exposed and developed. As a result, the etching resist 42 is formed on the surface of the base material 20.

In an etching process (Step S30), the copper foil layer 31, the copper plating layer 32, and the cap plating layer 61 at a portion where the etching resist 42 is not formed are etched to thereby form the wiring pattern 13, such as the land 14 or the conductor circuit 13A, is formed on the surface of the base material 20. Then, in a resist separation process (Step S31), by separating the etching resist 42 on the surface, the land 14 on which the projection portion 150 is formed, for example, is formed on the surface of the base material 20.

With respect to the projection portion 150 formed on the land 14 in the manufacturing processes of the Comparative Example, the projection plating layer 62 is formed on the cap plating layer 61 in the electrolytic copper plating process of Step S26. Then, the cross-sectional shape of the projection portion 150 is a reversed trapezium shape in which the base material surface side serves as the upper bottom. Furthermore, the outer peripheral edge portion of the projection portion 150 has a four layer structure of the copper foil layer 31, the copper plating layer 32, the cap plating layer 61 formed in the nonelectrolytic copper plating process of Step S22 and the electrolytic copper plating process of Step S23, and the projection plating layer 62 formed in the electrolytic copper plating process of Step S26.

The manufacturing processes of the Comparative Example require the resist formation processes of Step S28 to Step S31 for forming a circuit, the pattern exposure and development process, the resist separation process, and the like. The manufacturing processes of the Comparative Example are required to add the resist formation processes of Step S22 to Step S27, the pattern exposure and development process, the resist separation process, and the like in order to form the projection portion 150. In contrast, in the manufacturing processes of this Example, the projection portion 15 may be formed simply by adding the surface etching process.

In the manufacturing processes of the Comparative Example, when the positions on the surface of the base material 20 where the projection portions 150 are to be formed are different in the density, a difference occurs in the deposition of copper plating in the electrolytic copper plating process of Step S26 to thereby vary the height of the projection portions 150. Furthermore, since the area of the portion where the projection portion 150 is to be formed is small, it is difficult to perform copper plating which forms the projection plating layer 62. In contrast, in the manufacturing processes of this Example, copper plating which forms the cap plating layer 33 is given onto the surface of the base material 20 in the electrolytic copper plating process of Step 516B without being aware of the position where the projection portion 15 is to be formed. Therefore, the height of the projection portion 15 does not vary, and the treatment for performing copper plating is facilitated.

In the manufacturing processes of the Comparative Example, the position on the through hole 11 where the projection portion 150 is to be formed based on the touring hole is recognized, and then the pattern exposure and development process and the electrolytic copper plating process are performed at the position. However, the formation position of the projection portion 150 shifts due to an error of the formation position of the projection portion 150, contraction of the base material 20 due to moisture absorption of the base material 20, an accuracy error or expansion and contraction of a light-sensitive photomask, or the like. In contrast, in the manufacturing processes of this Example, the pattern exposure and development process is not required for forming the projection portion 15 and the projection portion 15 may be formed at the through hole position positioned by the touring hole. Moreover, since the positioning of lamination of the substrates 10 is performed based on the touring hole, the projection portions 15 of the substrates 10 to be laminated are made to face each other and press the conductive material 16 under melting. As a result, the lands 14 may be electrically connected by bringing the metal particles 161 of the conductive material 16 between the lands 14 into surface-to-surface contact to thereby form an aggregate of the particles.

In the manufacturing processes of the Comparative Example, the cross section of the projection portions 150 has a reversed trapezium shape, and therefore there is a problem in the strength of the projection portions 150 when pressing the conductive material 16 between the lands 14. In contrast, in the manufacturing processes of this Example, the cross section of the projection portions 15 has an approximately trapezoidal shape, which allows securing the strength of the projection portions 15 when pressing the conductive material 16 between the lands 14 by the projection portions 15.

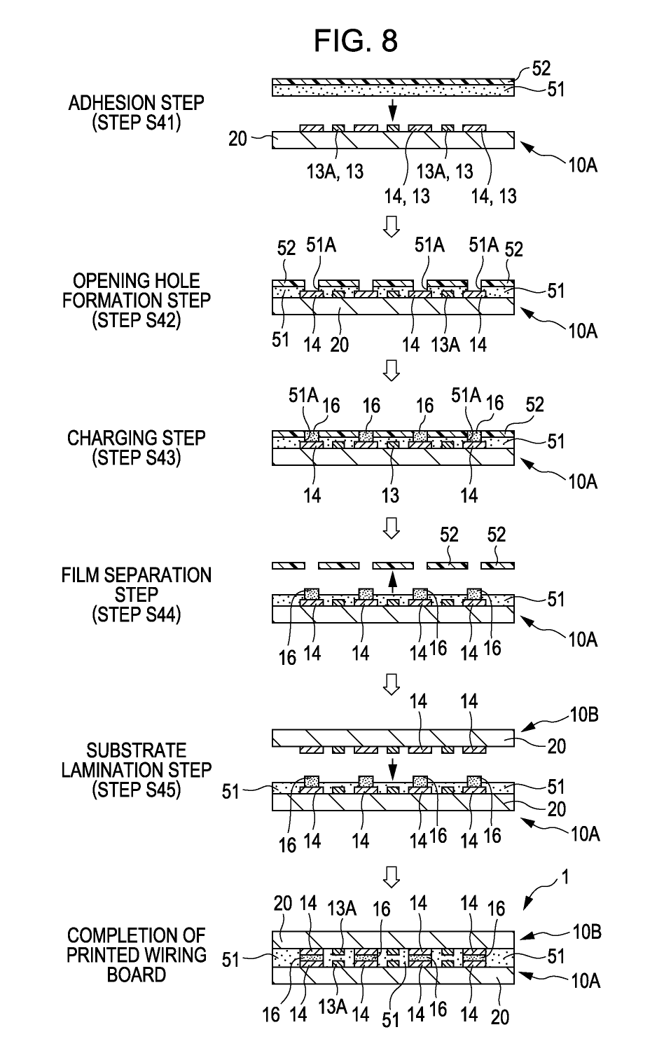

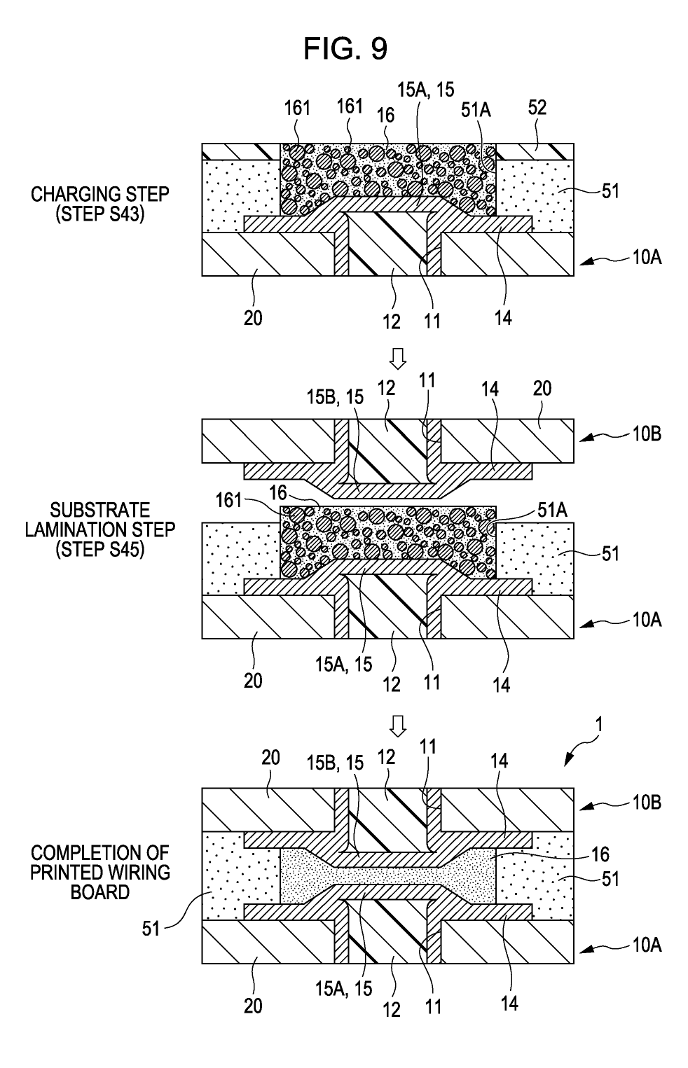

Next, manufacturing processes of the printed wiring board 1 including laminating two or more of the substrates 10, and then electrically connecting the lands 14 of the laminated substrates 10 with the conductive material 16 will be described. FIG. 8 illustrates views for describing the manufacturing processes of the printed wiring board 1. FIG. 9 illustrates views for describing the state of the conductive material 16 between the lands 14 among the manufacturing processes of the printed wiring board 1.

In the adhesion process (Step S41) illustrated in FIG. 8A, an adhesion sheet 51 containing thermosetting resin, such as an epoxy material, thermoplastic resin, such as polyetheretherketone resin, or the like is used. To both surfaces of the adhesion sheet 51, a miler film 52 of PET resin (polyethylene terephthalate resin) is stuck. In the adhesion process, the miler film 52 at the one side of the adhesion sheet 51 is separated, and then the adhesion sheet 52 at the side from which the miler film 52 is separated is disposed on the first substrate 10A on which the wiring patterns 13 including the lands 14, the conductor circuits 13A, and the like are formed. In this case, the adhesion sheet 51 is laminated while heating on the first substrate 10A in such a manner as to cover the wiring patterns 13 on the first substrate 10A. For example, when a prepreg of FR4 (Flame Retardant: Mark indicating the grade of flame resistance of a copper-plated laminated sheet which is a member of a printed wiring board) is used as the adhesion sheet 51, the heating temperature in such a case is about 90° C.

In an opening hole formation process (Step S42), opening holes 51A which are to be filled with the conductive material 16 are formed in the portions of the adhesion sheet 51 positioned on the lands 14 of the first substrate 10A. In the opening hole formation process, the portions of the adhesion sheet 51 positioned on the lands 14 of the first substrate 10A are irradiated with carbon dioxide laser for thermal sublimation of the portions of the adhesion sheet 51 to thereby form the opening holes 51A. The portions of the adhesion sheet 51 positioned on the lands 14 are recognized based on the touring hole described above. In the opening hole formation process, resin (smear) remains at the interface of the lands 14 due to the thermal sublimation, and therefore the resin on the interface of the lands 14 is removed by plasma treatment.

In a filling process (Step S43), the conductive material 16 is filled in the opening holes 51A formed on the lands 14 of the first substrate 10A. The miler film 52 of the adhesion sheet 51 laminated on the substrate surface is used as a stencil plate, and the conductive material 16 is filled in the opening holes 51A by a stencil printing method. The conductive material 16 is a material of a mixture of the metal particles 161 of powder in which molten metal and non-molten metal are mixed and an adhesion resin in which an adhesive and a curing agent are mixed. For the molten metal, a tin bismuth(I) material or the like is used, for example. For the non-molten metal, a material obtained by plating copper with antioxidant silver is used, for example. For the adhesive, an epoxy adhesive is used, for example. For the curing agent, an acid anhydride curing agent is used, for example. To the conductive material 16, succinic acid is added as an active agent for the purpose of increasing the wettability (bonding properties) of the metallic powder when bonding. In the filling process, the conductive material 16 is filled in the opening holes 51A by a stencil printing method, and therefore the process is facilitated. In a film separation process (Step S44), after filling the conductive material 16 in the opening holes 51A on the lands 14, the miler film 52 is separated from one side of the adhesion sheet 51 laminated on the substrate surface.

In a substrate lamination process (Step S45), after separating the miler film 52, the second substrate 10B to be laminated at the opposite side is disposed on the first substrate 10A in which the conductive material 16 is filled in the opening holes 51A on the lands 14. When the second substrate 10B is disposed on the first substrate 10A, positioning is performed using positioning pins for the first substrate 10A and the second substrate 10B. Then, the positioning of the first substrate 10A and the second substrate 10B is performed using the positioning pins, and are pressurized in the lamination direction in the vacuum state while heating. Therefore, the situation in which a void generates in the adhesion layer serving as the adhesion sheet 51 may be avoided.

The first substrate 10A and the second substrate 10B press the conductive materials 16 under melting filled in the opening holes 51A in the lamination direction by the projection portions 15A and 15B on the lands 14 of the substrate to be laminated. As a result, as illustrated in FIG. 9, by pressing the conductive materials 16 under melting in the lamination direction by the projection portions 15A and 15B, the capacity of the projection portions 15A and 15B absorb the volume of the resin ingredients of the conductive material 16. Then, the metal particle 161 of the conductive material 16 are brought into surface-to-surface contact and aggregated to thereby form a cured product of the conductive material 16. Then, by electrically connecting the lands 14 with the cured product of the conductive material 16, the printed wiring board 1 is completed in which the first substrate 10A and the second substrate 10B are laminated. For convenience of description, the description is given with reference to an example of the printed wiring board 1 in which two substrates of the first substrate 10A and the second substrate 10B are laminated but a multilayer printed wiring board may be manufactured according to the lamination number of the substrates 10.

In this Example, a given amount of the copper plating layer 32 is etched using the hole filling material 12 filled in the through hole 11 on the surface of the base material 20 to thereby make the end portion 12A of the hole filling material 12 project from the surface, and cap plating the end portion 12A to thereby form the projection portion 15 on the land 14.

Furthermore, in this Example, after filling the conductive material 16 in the opening holes 51A of the adhesion sheet 51 laminated on the substrate 10, the conductive material 16 under melting were pressed in the lamination direction by the projection portions 15 of the substrates 10 to be laminated. As a result, the first substrate 10A and the second substrate 10B press the conductive materials 16 under melting by the projection portions 15, so that the metal particles 161 of the conductive material 16 are aggregated in the surface-to-surface contact state to form a cured product, and then the lands 14 may be electrically connected with the cured product of the conductive material 16.

In this Example, since the projection portion 15 may be formed on the land 14 of the substrate by the surface etching process even when a special process, such as a photo process, a bumping process, a transfer process, or a printing process, is not added, a complicated process is not required, which reduces the manufacturing cost.

Moreover, in this Example, since the cross sectional structure of the projection portion 15 formed on the lands 14 has an approximately trapezoidal shape, the strength of the projection portions 150 when pressing the conductive material 16 may be secured as compared with the case in which the cross sectional structure of the projection portions 150 of the Comparative Example has a reversed trapezium shape.

In this Example, since the cross sectional structure of the projection portion 15 formed on the land 14 has an approximately trapezoidal shape, the contact surface area when pressing the conductive material 16 by the projection portions 15 is large as compared with the case where the cross sectional structure of the projection portion has an approximately triangular shape, for example. The conductive materials 16 may be pressed in surface-to-surface contact while securing the strength of the projection portions.

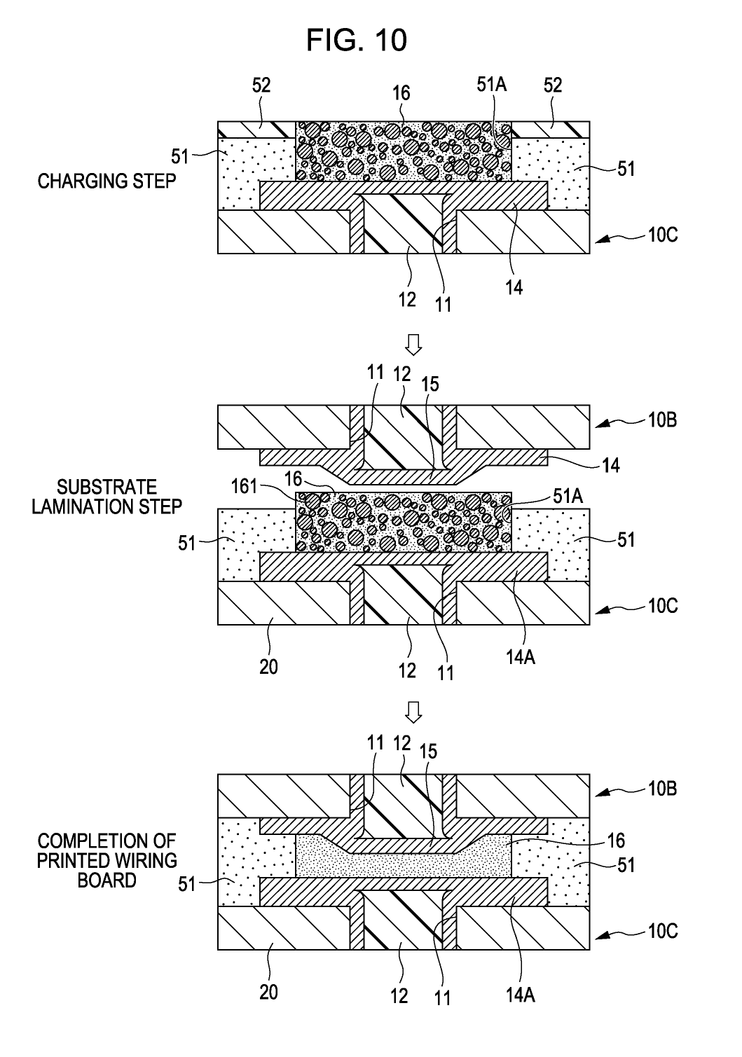

In the above-described Example, by laminating the substrates 10 and pressing the conductive material 16 between the lands 14 by the projection portions 15, the metal particles 161 of the conductive material 16 are aggregated in surface-to-surface contact, and the lands 14 are stably electrically connected by the conductive material 16. FIG. 10 illustrates views for describing the state of the conductive material 16 between the lands 14 among the manufacturing processes of the printed wiring board 1 of another Example. On the surface of a third substrate 10C illustrated in FIG. 10, a land 14A having no projection portion 15 is formed. On the third substrate 10C, the adhesion sheet 51 is laminated. In a filling process, the conductive material 16 is filled in an opening hole 51A formed with the adhesion sheet 51 on the land 14A of the third substrate 10C. In a substrate lamination process, when laminating the second substrate 10B on the third substrate 10C, the conductive material 16 under melting filled in the opening hole 51A on the land 14A of the third substrate 10C may be pressed in the lamination direction by the projection portion 15 formed on the land 14 of the second substrate 10B. In this case, the amount of the conductive material 16 is increased. As a result, the third substrate 10C and second substrate 10B press the conductive material 16 under melting in the lamination direction by the projection portion 15, so that the metal particles 161 of the conductive material 16 are aggregated in the state of surface-to-surface contact to thereby form a cured product. Then, the land 14 and the lands 14A may be electrically connected with the cured product of the conductive material 16.

The projection portion 15 is formed on the land 14 of one of the substrates 10 among the substrates 10 to be laminated and also the projection portion 15 of the land 14 of the other substrate 10 is made small, and the amount of the conductive material 16 is increased, and then the conductive material 16 between the lands 14 may be pressed by the projection portions 15.

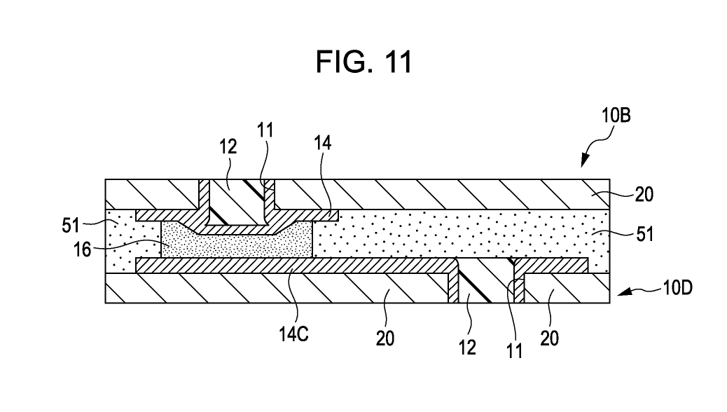

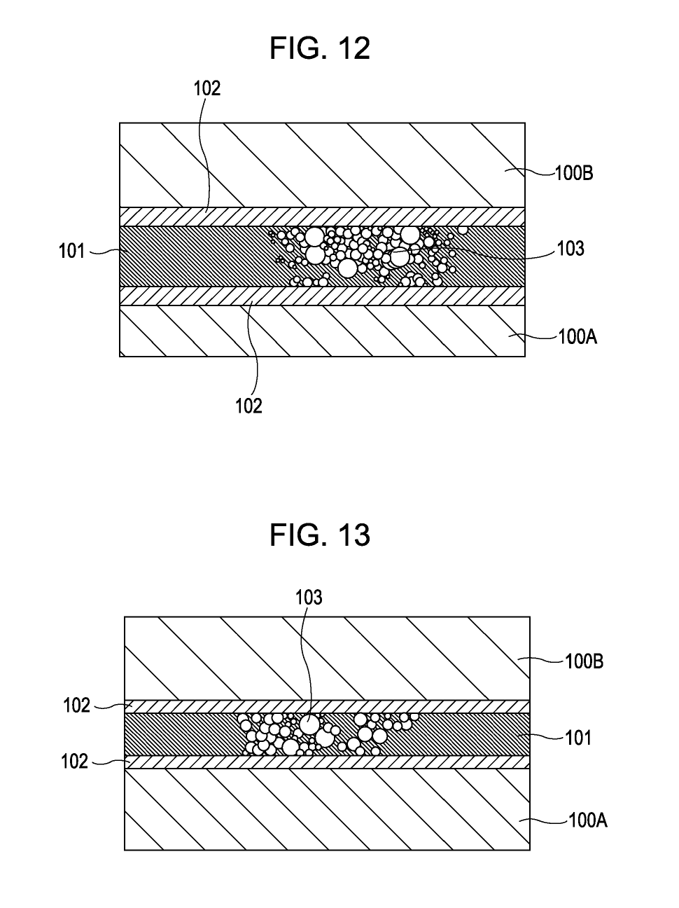

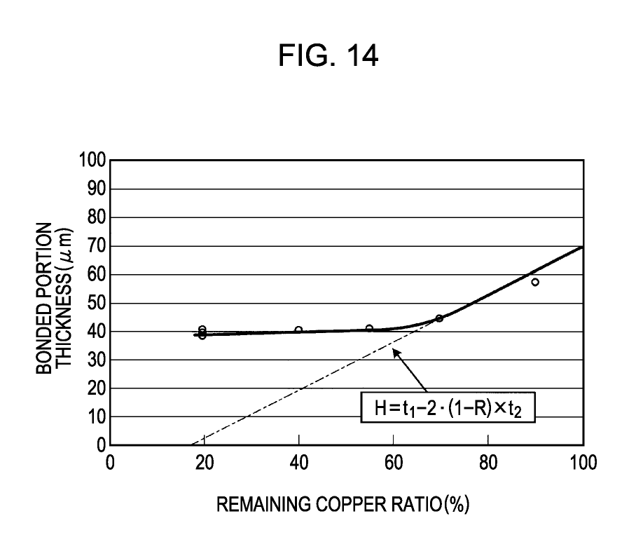

In the above-described Example, the conductive material 16 between the land 14 of the first substrate 10A and the land 14 of the second substrate 10B was pressed by the projection portion 15A of the first substrate 10A and the projection portion 15B of the second substrate 10B. Then, the conductive material 16 is disposed concentrically with the through holes 11 of the first substrate 10A and the second substrate 10B. However, the conductive material 16 may be disposed as illustrated in FIG. 11. FIG. 11 is a cross sectional view in which a portion of a printed wiring board of another Example is omitted. As illustrated in FIG. 11, the through hole 11 of the second substrate 10B and the through hole 11 of a fourth substrate 10D at the opposite side thereto may not be concentrically provided. A land 14C of the fourth substrate 10D is not provided concentrically with the through holes 11 but is electrically connected to the through holes 11.

With respect to the second substrate 10B and the fourth substrate 10D, by pressing the conductive material 16 in the lamination direction by the projection portion 15 formed on the land 14 of the second substrate 10B, the land 14 of the second substrate 10B and the land 14C of the fourth substrate 10D may be electrically connected by the conductive material 16.

In the above-described Examples, the cross sectional structure of the projection portion 15 was an approximately trapezoidal shape but the shape is not limited thereto and may have a structure in which the metal particles 161 of the conductive material 16 are brought into surface-to-surface contact with each other by pressing the conductive material 16 in the lamination direction simply by adding the surface etching process described above.

In the above-described examples, the numerical values, such as dimension, of materials for manufacturing the printed wiring board 1 are specifically specified but the specified numerical values are described merely as one example of the present invention and the technical idea of the present invention is not limited by the numerical values.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A method for manufacturing a printed wiring board, comprising:
filling material in through holes formed in first lands on a first substrate;
forming projection portions projecting from the first lands on the surface of the material of the through holes;
placing a conductive material on the first lands; and
electrically connecting the first lands of the first substrate and second lands of second substrate by pressing the conductive material under melting filled between the first and second lands in the lamination direction of the substrates by the projection portions when laminating the substrates in such a manner that the lands of the other substrate face the lands of the substrate for aggregation of the conductive material.

2. The method for manufacturing a printed wiring board according to claim 1, wherein
the forming the projection portion including:
etching a metal layer on the first substrate in such a manner as to leave a given amount of the metal layer in such a manner that the end portion of the material filled in the through holes to project from the metal layer: and
forming the projection portion by cap plating the end portion of the material filled in the through holes projecting from metal layer.

3. The method for manufacturing a printed wiring board according to claim 1, wherein
the cross sectional shape of the projection portion is an approximately trapezoidal shape.

4. The method for manufacturing a printed wiring board according to claim 1, wherein
the material filled in the through holes is a resin material.

5. The method for manufacturing a printed wiring board according to claim 1, wherein
the conductive material contains metal particles of a low melting point metal and a resin ingredient, and
in the step of electrically connecting with the conductive material, the metal particles of the conductive material are brought into surface-to-surface contact and aggregate by pressing the conductive material under melting in the lamination direction of the substrates by the projection portions, and the land of the substrate and the land of the other substrate are electrically connected by the aggregation of the conductive material.

6. The method for manufacturing a printed wiring board according to claim 1, wherein
in the step of electrically connecting with the conductive material, the lands of the substrate and the lands of the other substrate are electrically connected by the aggregation of the conductive material by pressing the conductive material under melting in the lamination direction by the projection portions on the lands of the substrate and the projection portions on the lands of the other substrate.

7. A printed wiring board, comprising:
a first substrate having a base material, through holes formed in the thickness direction of the base material, a hole filling material filled in the through holes, lands formed on the base material surface in connection to the through holes, and projection portions formed on the lands using the hole filling material; and
a second substrate having a base material, through holes, and lands; and
a conductive material for electrically connecting the land of the first substrate and the land of the second substrate.

8. The printed wiring board according to claim 7, wherein
the second substrate has the projection portion formed on the land of the substrate, and the projection portion of the first substrate and the projection portion of the second substrate are electrically connected by the conductive material.

9. The printed wiring board according to claim 7, wherein
the land on which the projection portion is formed has a three layer structure including:
a metal foil layer on the base material surface;
a metal plating layer formed over metal plating on the inner wall surface of the through hole; and
a cap plating layer formed over the end portion of the hole filling member.

10. An electronic device, comprising a printed wiring board mounted thereon, the printed wiring board having:
a first substrate having a base material, through holes formed in the thickness direction of the base material, a hole filling material filled in the through holes, lands formed on the base material surface in connection to the through holes, and projection portions formed on the lands using the hole filling material; and
a second substrate having a base material, through holes, and lands, and
a conductive material for electrically connecting the land of the first substrate and the land of the second substrate.
